(19) United States
(12) Patent Application Publication
(10) Pub. No.: US 2012/0173175 A1
(43) Pub. Date: Jul. 5, 2012

(54) PHOTODIODE ARRAY WITH ALGORITHM-BASED CROSSTALK REDUCTION

(76) Inventors: Deepak DEVICHARAN, Horseheads, NY (US); Peter G. Wigley, Corning, NY (US)

(21) Appl. No.: 12/982,559

(22) Filed: Dec. 30, 2010

(51) Int. Cl. G01R 21/06; G01J 1/42

(52) U.S. Cl. 702/60; 356/218

(57) ABSTRACT

A photodiode (PD) array accurately measures incident optical power on each of the PDs in the array by eliminating the effect of crosstalk between the individual PDs. Crosstalk within the PD array is removed by measuring the current generated by each PD in the array and generating a corrected optical power value for each PD that is based on the measured current for each PD and on coupling coefficients associated with other PDs in the array. The coupling coefficients are determined during a previous calibration procedure.

### BACKGROUND OF THE INVENTION

1. Field of the Invention

Embodiments of the present invention relate generally to optical communication systems and components and, more particularly, to a photodiode array with algorithm-based crosstalk reduction.

2. Description of the Related Art

Photodiodes are used to perform optical power measurement and monitoring in a range of devices, including optical amplifiers, wavelength selective switches, and other systems that benefit from the monitoring of optical channel performance. In devices using multiple photodiodes, such as wavelength-division-multiplexing (WDM) devices, the size and cost of the relatively large numbers of photodiodes required can be problematic. Manufacturing multiple photodiodes together as an integrated detector array can greatly reduce the size and unit cost of the photodiodes, such as when a large number of semiconductor photodiodes are fabricated from a common substrate. However, such photodiode arrays are more readily subject to crosstalk between the elements of the array, which can affect the accuracy and resolution of the detector array.

Crosstalk between adjacent photodiode elements of a detector array is an important parameter of the performance of the array and can be due to either electrical or optical crosstalk. Electrical crosstalk occurs when carriers that are photo-generated by one photodiode element diffuse across a common substrate and are collected by a neighboring photodiode element in the array. Optical crosstalk occurs when the light energy itself is partially incident on neighboring elements, and includes the effects of photon refraction, reflection at boundaries, and external and internal scattering in a photodiode array.

FIG. 1 schematically illustrates electrical and optical crosstalk occurring in a photodiode array 100. Photodiode array 100 includes a plurality of photodiodes (PDs) 101-104 formed on a common semiconductor substrate 110. In operation, incident light 121-124 strikes PDs 101-104, respectively. In response, each of PDs 101-104 produces an electrical output 131-134. Ideally, the amplitude of electrical output 131 is directly proportional to the optical energy contained in incident light 121, the amplitude of electrical output 132 is directly proportional to the optical energy contained in incident light 122, and so on. In practice, the electrical output 131-134 of each of PDs 101-104 is affected by crosstalk from neighboring PDs. For example, in the case of PD 102, optical leakage 141 from PD 101 and optical leakage 143 from PD 103 will affect the value of electrical output 132 from PD 102. Similarly, electrical leakage 151 from PD 101 and electrical leakage 153 from PD 103 will also affect the value of electrical output 132 from PD 102. Thus, the electrical outputs 131-134 of photodiode array 100 are inherently inaccurate, particularly when the elements of photodiode array 100 are fabricated on common semiconductor substrate 110.

The effect of crosstalk can be reduced between elements of a PD array through structural and other design changes to the PD devices in the array. For example, optical crosstalk can be reduced by the formation of a radiation shield or other optical energy barrier between the PD array elements during the process of fabricating the PD elements. Similarly, electrical crosstalk can be reduced by forming electrical barriers between the PD array elements. However, such techniques add complexity and cost to the manufacturing process. Accordingly, there is a need in the art for PD arrays having reduced crosstalk without the presence of additional structures in the PD array.

### SUMMARY OF THE INVENTION

One or more embodiments of the present invention provide a photodiode (PD) array for measuring incident optical power and a method of accurately measuring optical power of light incident on each of the PDs in such an array. The effect of crosstalk between the individual PDs of the array is removed by measuring the current generated by each PD in the array and generating a corrected optical power value for each PD that is based on the measured current for each PD and on coupling coefficients associated with other PDs in the array, where the coupling coefficients are determined during a previous calibration procedure. In some embodiments, the corrected optical power values may be solved for simultaneously using a system of linear equations, where each equation expresses the measured optical power value for a PD in the array as a function of the corrected optical power value for the PD and the appropriate coupling coefficients.

In a photodiode array, a method of measuring optical power of light incident on photodiodes according to an embodiment of the present invention comprises measuring a current generated by a photodiode in the array in response to the light incident on the photodiode and generating an optical power value based on the measured current and correction factors associated with other photodiodes in the array.

A computer-readable storage medium according to another embodiment of the present invention comprises instructions to be executed by a processing unit of an optical power monitoring device to carry out the steps of measuring a current generated by a photodiode in a photodiode array in response to the light incident on the photodiode and generating an optical power value based on the measured current and correction factors associated with other photodiodes in the array.

According to another embodiment of the present invention, an optical power measuring system comprises a processor and a photodiode array, wherein the processor is configured to perform the steps of measuring a current generated by a photodiode in the photodiode array in response to the light incident on the photodiode, and generating an optical power value based on the measured current and correction factors associated with other photodiodes in the array.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 schematically illustrates electrical and optical crosstalk occurring in a photodiode array.

FIG. 2 schematically illustrates a calibration apparatus for determining coupling coefficients between photodiode (PD) elements of a PD array, according to embodiments of the invention.

FIG. 3 schematically illustrates an exemplary embodiment of a processor, according to embodiments of the invention.

FIG. 4 is a flow chart that summarizes, in a stepwise fashion, a method for determining coupling coefficients between PD elements, according to embodiments of the invention.

FIG. 5 is a flow chart that summarizes, in a stepwise fashion, a method for measuring optical power of light incident on PDs in a PD array, according to embodiments of the invention.

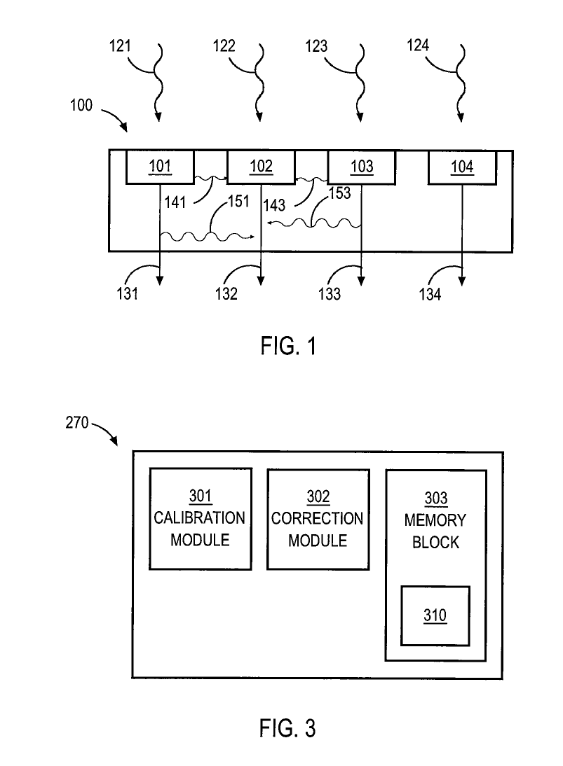

For clarity, identical reference numbers have been used, where applicable, to designate identical elements that are common between figures. It is contemplated that features of one embodiment may be incorporated in other embodiments without further recitation.

### DETAILED DESCRIPTION

One or more embodiments of the present invention provide a low-crosstalk photodiode (PD) array for measuring incident optical power and a method for accurately measuring optical power of light incident on each of the PDs in an array that removes the effect of crosstalk. Coupling coefficients quantifying the optical and/or electrical coupling between each PD of the array are determined during a previous calibration procedure and are used to remove the effect of crosstalk on the different outputs of the PD array.

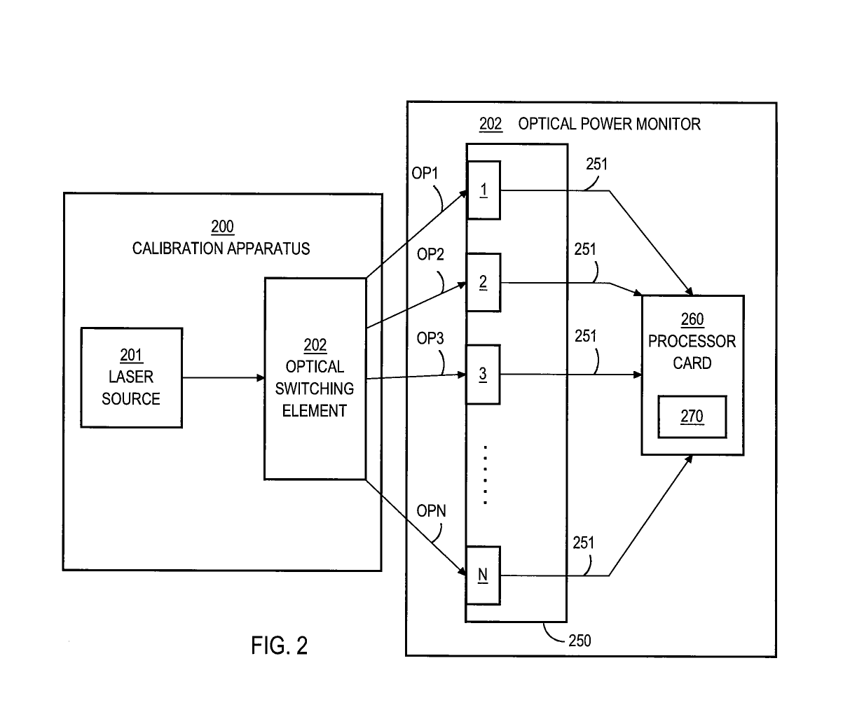

FIG. 2 schematically illustrates a calibration apparatus 200 for determining coupling coefficients between the PD elements 1-N of a PD array 250, according to embodiments of the invention. Calibration apparatus 200 includes a laser source 201 optically coupled to an optical switching element 202, which is in turn optically coupled to optical power monitor 220. Laser source 201 is a laser configured to produce optical output in the wavelength band and power range in which the PD elements 1-N of PD array 250 are intended to operate. The number of PD elements, N, in PD array 250 may be a one-, two-, or three-digit integer or larger. In some embodiments, laser source 201 may be a tunable laser, such as when PD elements 1-N are configured to measure the optical energy of different bandwidths in a wavelength-division-multiplexing (WDM) application. In such embodiments, laser source 201 may be tuned to the different wavelengths corresponding to particular WDM wavelength channels. Thus, when laser source 201 is a tunable laser source, a calibration procedure may be performed with calibration apparatus 200 to generate a complete set of coupling coefficients between PD elements 1-N for each wavelength of light that may be directed to PD array 250. Such a calibration procedure is described in greater detail below. Optical switching element 202 is configured to optically couple laser source 201 to any one of the PD elements 1-N of PD array 250 with minimal loss via optical paths OP1-OPN as shown. Optical paths OP1-OPN may be optic fibers, waveguides, free space optical paths, and/or a combination thereof. The optical loss that occurs between optical switching element 202 and each of PD elements 1-N is known in order to maximize accuracy of the calibration procedure for determining coupling coefficients.

Optical power monitor 220 includes PD array 250 and a processor card 260. Optical power monitor 220 is a device that may be used for monitoring optical power of multiple light sources, and may be incorporated into any system or device that includes the function of optical power monitoring. For example, optical power monitor 220 may be an integrated component of an optical amplifier card, a wavelength selective switch, or other performance-monitoring devices used in a WDM application, and may be used to quantify the performance of WDM data channels, optical supervisor channels, etc.

PD array 250 includes a plurality of N PD elements, each of which is configured to monitor the optical power of light incident thereon. In some embodiments, PD elements 1-N may be part of a monolithically integrated semiconductor sensor array and fabricated on a common substrate, such as an InP or InSb substrate. When light is incident on one of the PD elements of PD array 250, the PD element integrates the incident optical energy and produces an electrical output 251 that is proportional to the optical energy in said bandwidth. Thus, in operation, PD array 250 may be utilized as an optical power monitor for a plurality of light sources, such as individual WDM data channels that have been demultiplexed from a WDM optical signal.

Processor card 260 includes electronic components and other hardware for measuring the electrical output 251 of each PD element 1-N and is configured to control the normal operation of optical power monitor 220. Processor card 260 is also configured to perform calibration measurements and the calculation of coupling coefficients between PD elements 1-N based on said measurements. Processor card 260 further includes a processor 270, which is configured to perform calculations and execute instructions for the operation and calibration of optical power monitor 220. Processor 270 can be any appropriate processor including but not limited to general-purpose processors such as microprocessors and digital signal processors (DSP), or a special-purpose processor such as an application specific integrated circuit (ASIC) or field-programmable gate array (FPGA).

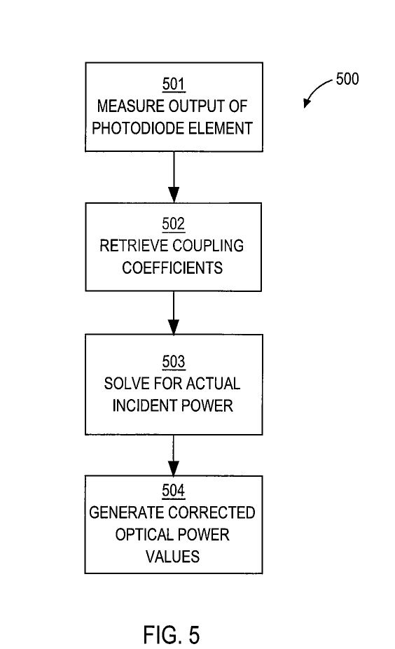

FIG. 3 schematically illustrates an exemplary embodiment of processor 270, according to embodiments of the invention. Processor 270 includes a calibration module 301, a correction module 302, and a memory block 303. Calibration module 301 is configured to execute the appropriate instructions and computations for optical power monitor 220 to perform calibration procedures and to calculate coupling coefficients between each PD element of PD array 250 and to store these coupling coefficients in memory block 303. For example, calibration module 301 may be used to control laser source 201 and optical switching element 202 during the calibration procedure. One such calibration procedure for determining coupling coefficients is disclosed below. Correction module 302 is configured to update measured optical power values to actual optical power values by applying coupling coefficients to the optical power values measured by each of PD elements 1-N and solving for the actual optical power values for each PD element. A method of computing actual optical power values for each PD element is described below in conjunction with FIG. 5. Calibration module 301 and correction module 302 may be logical modules, dedicated hardware, or a combination of both. Depending on the desired configuration, memory block 303 may be of any type including but not limited to volatile memory (such as RAM), non-volatile memory (such as ROM, flash memory, etc.) or any combination thereof. Coupling coefficients 310 are stored in memory block 303 and are retrieved during normal operation of optical power monitor 220 to eliminate the effect of crosstalk on electrical outputs 251 of PD elements 1-N.

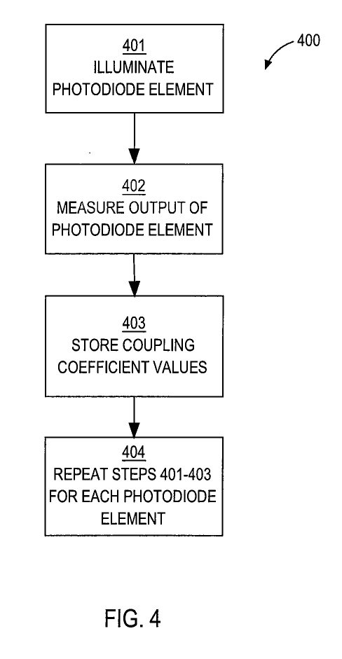

In operation, calibration apparatus 200, when coupled to optical power monitor 220, determines coupling coefficients between PD elements 1-N of a PD array 250. FIG. 4 is a flow chart that summarizes, in a stepwise fashion, a method 400 for determining coupling coefficients between PD elements 1-N, according to embodiments of the invention. Method 400 is described in terms of an optical power monitoring device substantially similar optical power monitor 220, described above. However, other optical power monitoring devices may also benefit from the use of method 400. Although the method steps are described in conjunction with FIG. 4, persons skilled in the art will understand that any system configured to perform the method steps, in any order, falls within the scope of the present invention. Prior to the first step of method 400, the optical loss of optical paths OP1-OPN is determined, to maximize the accuracy of the coupling coefficients determined in method 400.

The method begins in step 401, in which laser source 201 is coupled to a single PD element via optical switching element 202 and optical path OP1. Thus, one PD element is illuminated with a known quantity of optical power and the remaining PD elements are completely “dark,” i.e., no incident light energy is directed thereto. For clarity, the illuminated PD element is herein referred to as PD element M, where M may be any of the 1 to N PD elements in PD array 250.

In step 402, processor 270 measures electrical output 251 of each of PD elements 1-N. Electrical output 251 of the illuminated PD element, i.e., PD element M, is approximately proportional to the optical power of light thereon, but includes significant inaccuracy due to optical and electrical crosstalk from some or all of the other PD elements in PD array 250. Electrical output 251 of each dark PD element is, within measurement error, exactly proportional to the crosstalk between the PD element M and the dark PD element. The value of each electrical output 251 measured in step 402 can be used as coupling coefficients that together can be used to solve for the actual incident optical power on PD elements 1-N. The use of coupling coefficients to solve for actual incident power is described below in steps 403-405 of method 400 and step 503 of method 500.

In step 403, processor 270 stores the coupling coefficient values measured in step 402 in memory block 303. Because the coupling coefficient values stored are each proportional to the crosstalk between the dark PD elements and PD element M, these coupling coefficient values may be used in Equation 1. Equation 1 relates the actual optical power P_{incident} that is incident on PD element M to the measured optical power P_{measured} that is reported by PD element M, where P_{measured} includes the effect of crosstalk from all other PD elements in PD array 250 on PD element M:

$${P}_{measured} ( M ) = {\sum }_{j = 1}^{N} {C}_{Mj} {P}_{incident} ( j ) \qquad ( 1 )$$

where M is a specific PD element, N is the total number of PD elements in PD array 250, and c_{Mj} is the coupling coefficient that represents the effect of crosstalk from PD element j on PD element M. It is noted that Equation 1 holds true even when PD element M is not the only PD element in PD array 250 that is being illuminated. By way of example, for the first PD element (M=1) in a 4-element PD array, substitution of the appropriate values into Equation 1 yields Equation 2:

P_{measured}(1)=C₁₁P_{inc}(1)+C₁₂P_{inc}(2)+C₁₃P_{inc}(3)+C₁₄P_{inc}(4) (2)

In practice, the contribution to crosstalk to PD element M by other than the closest PD elements in PD array 250 may be negligible. In some embodiments, for simplicity, only the coupling coefficients of PD elements proximate and/or adjacent to PD element M are stored in step 403, and all other coupling coefficient values are assumed to be zero.

The series of coupling coefficients stored in step 403, i.e., c_{M1}, c_{M2}, c_{M3}, . . . c_{MN}, can be used to populate the Mth row of an N×N matrix, herein referred to as a “crosstalk matrix.” As described below, the N×N crosstalk matrix can be used to simultaneously solve for the actual incident optical power P_{incident} for each of PD elements 1-N. In some embodiments, prior to storing the coupling coefficients for PD element M measured in step 402, PD element M is set as the reference element and the coupling coefficients are normalized to 1 for the self-coupling element in the series. In other words, the coupling coefficient representing the coupling of PD element M to itself is set to one and the remaining coupling coefficient values are adjusted proportionally, i.e., when M=j, c_{Mj}=1. This normalization process facilitates later matrix inversion of the crosstalk matrix when solving for the actual incident power P_{incident}.

In step 404, steps 401-403 are repeated for each PD element in PD array 250, so that each of PD elements 1-N is treated as element M. In this way, a series of coupling coefficients is collected for each PD element in PD array 250, so that the N×N crosstalk matrix can be constructed.

In some applications, crosstalk between PD elements may vary significantly as a function of wavelength. Consequently, the coupling coefficients measured in method 400 may not be accurate when different wavelengths of light are monitored by optical power monitor 220. In some embodiments, multiple sets of coupling coefficients are measured, where a different set of coupling coefficients is measured for each wavelength or wavelength band of interest. In such embodiments, method 400 is repeated for each wavelength or wavelength band. Subsequently, when optical power monitor 220 is in operation, the crosstalk matrix that is used to solve for the actual incident power P_{incident} is constructed by selecting the appropriate coupling coefficients for each PD element from the different wavelength-dependent sets of coupling coefficients, based on what particular wavelength of light is incident on each of the PD elements.

In operation, optical power monitor 220 determines the actual incident power on each of PD elements 1-N by measuring optical power at each PD element and applying a crosstalk matrix of coupling elements to solve the system of equations that expresses the measured optical power for all PD elements as a function of actual incident power on each PD element and the predetermined coupling coefficients. The predetermined coupling coefficients are found using method 400 and the system of equations is solved by constructing a crosstalk matrix of said coupling coefficients. Thus, application of the appropriate coupling coefficients eliminates the effect of crosstalk on the electrical outputs of PD array 250.

FIG. 5 is a flow chart that summarizes, in a stepwise fashion, a method 500 for measuring optical power of light incident on PDs in a PD array, according to embodiments of the invention. Method 500 is described in terms of an optical power monitoring device substantially similar optical power monitor 220, described above. However, other optical power monitoring devices may also benefit from the use of method 500. Although the method steps are described in conjunction with FIG. 5, persons skilled in the art will understand that any system configured to perform the method steps, in any order, falls within the scope of the present invention. Prior to the first step of method 500, one or more sets of coupling coefficients are determined using method 400. Multiple sets of coupling coefficients may be determined if the wavelength-dependence of crosstalk is assumed to be significant and if different wavelengths or wavelength bands are incident on different PD elements of PD array 250 during normal operation.

The method begins in step 501, in which processor 270 measures electrical output 251 of each PD element of PD array 250. It is noted that electrical output 251 of each PD element includes significant inaccuracy due to optical and electrical crosstalk from some or all of the other PD elements in PD array 250.

In step 502, processor 270 retrieves the appropriate coupling coefficients from memory block 303. In embodiments in which different wavelengths or wavelength bands are incident on different PD elements, the coupling coefficients may be selectively retrieved from multiple coupling coefficient sets.

In step 503, processor 270 solves the system of equations represented by Equation 3:

[P_{measured}]=[C][P_{incident}] (3)

where [P_{measured}] is the vector representing the electrical outputs 251 of PD elements 1-N measured in step 501, [C] is the crosstalk matrix constructed in step 502, and [P_{incident}] is the vector representing the actual incident power of light incident on each of the PD elements 1-N.

In step 504, processor 270 generates a corrected optical power value for each PD element based on the solution of Equation 3 for [P_{incident}].

In sum, embodiments of the invention provide a PD array for measuring incident optical power and a method of accurately measuring optical power of light incident on each of the PDs in such an array. During operation, the effect of crosstalk between the individual PDs of the array is removed by measuring the current generated by each PD in the array and generating a corrected optical power value for each PD that is based on the measured current for each PD and on coupling coefficients associated with other PDs in the array. Thus, crosstalk can be greatly reduced in a PD array without modifying the structures of the PD elements.

While the foregoing is directed to embodiments of the present invention, other and further embodiments of the invention may be devised without departing from the basic scope thereof, and the scope thereof is determined by the claims that follow.

I claim:

1. A method of measuring optical power of light incident on photodiodes in a photodiode array, the method comprising:
measuring a current generated by a photodiode in the array in response to the light incident on the photodiode; and
generating an optical power value based on the measured current and correction factors associated with other photodiodes in the array.

2. The method of claim 1, wherein the correction factors are coupling coefficients proportional to crosstalk between the photodiode and the other photodiodes.

3. The method of claim 1, wherein a portion of the correction factors are coupling coefficients proportional to crosstalk between the photodiode and the other photodiodes when illuminated by a light in a first wavelength band and a remainder of the correction factors are coupling coefficients proportional to crosstalk between the photodiode and the other diodes when illuminated by light in a second wavelength band.

4. The method of claim 1, wherein the correction factors are proportional to crosstalk between the photodiode and adjacent photodiodes.

5. The method of claim 1, wherein the correction factors are coupling coefficients determined in a calibration procedure.

6. The method of claim 5, wherein the calibration procedure comprises illuminating a single photodiode in the array with light and measuring the output of all photodiodes in the array.

7. The method of claim 1, wherein generating an optical power value comprises constructing a crosstalk matrix with the correction factors.

8. The method of claim 7, wherein generating an optical power value further comprises solving a system of linear equations using the crosstalk matrix.

9. The method of claim 1, wherein the correction factors are coupling coefficients determined in a calibration procedure.

10. A computer-readable storage medium comprising instructions to be executed by a processing unit of an optical power monitoring device to carry out the steps of:
measuring a current generated by a photodiode in a photodiode array in response to the light incident on the photodiode; and
generating an optical power value based on the measured current and correction factors associated with other photodiodes in the array.

11. The computer-readable storage medium of claim 10, wherein the correction factors are coupling coefficients proportional to crosstalk between the photodiode and the other photodiodes.

12. The computer-readable storage medium of claim 10, wherein a portion of the correction factors are coupling coefficients proportional to crosstalk between the photodiode and the other photodiodes when illuminated by a light in a first wavelength band and a remainder of the correction factors are coupling coefficients proportional to crosstalk between the photodiode and the other diodes when illuminated by light in a second wavelength band.

13. The computer-readable storage medium of claim 10, wherein the correction factors are proportional to crosstalk between the photodiode and adjacent photodiodes.

14. The computer-readable storage medium of claim 10, wherein the correction factors are coupling coefficients determined in a calibration procedure.

15. The computer-readable storage medium of claim 14, wherein the calibration procedure comprises illuminating a single photodiode in the array with light and measuring the output of all photodiodes in the array.

16. The computer-readable storage medium of claim 10, wherein generating an optical power value comprises constructing a crosstalk matrix with the correction factors.

17. The computer-readable storage medium of claim 16, wherein generating an optical power value further comprises solving a system of linear equations using the crosstalk matrix.

18. An optical power measuring system comprising:
a processor; and
a photodiode array,
wherein the processor is configured to perform the steps of:
measuring a current generated by a photodiode in the photodiode array in response to the light incident on the photodiode; and
generating an optical power value based on the measured current and correction factors associated with other photodiodes in the array.

19. The optical power measuring system of claim 18, further comprising a memory unit configured to store instructions that, when executed by the processing unit, cause the processor to perform the steps of measuring and generating.

20. The optical power measuring system of claim 18, wherein the correction factors are coupling coefficients proportional to crosstalk between the photodiode and the other photodiodes.

21. The optical power measuring system of claim 19, wherein the processor is configured to perform the calibration procedure.
